(19) United States
(12) Patent Application Publication
(10) Pub. No.: US 2002/0105789 A1
(43) Pub. Date: Aug. 8, 2002

(54) Semiconductor package for multi-chip stacks

(75) Inventors: Yi-Hsin Chen, Taichung (TW); Lien-Chih Chan, Taichung (TW); Chi-Chuan Wu, Taichung (TW)

Correspondence Address: Ladas & Parry, 26 West 61st Street, New York, NY, 10023, US

(73) Assignee: SILICONWARE PRECISION INDUSTRIES CO., LTD.

(21) Appl. No.: 09/776,538

(22) Filed: Feb. 2, 2001

(51) Int. Cl. H05K 7/10

(52) U.S. Cl. 361/767

(57) ABSTRACT

The present invention discloses a semiconductor package for multi-chip stacks, which could be utilized in a BGA package or a flip chip package. The substrate of the semiconductor package has a hollow region, a first chip of the multi-chip stack is placed above the hollow region of the substrate, and a second chip of the multi-chip stack is adhered on the active surface of the first chip and placed in the hollow region of the substrate. The first chip is electrically connected to the substrate through a plurality of solder bumps, and the second chip is electrically connected to the substrate through a plurality of bonding wires.

### BACKGROUND OF THE INVENTION

1. Field of the Invention

The present invention relates to a semiconductor package for multi-chip stack and, particularly, to a semiconductor package for multi-chip stacks which reduces the profile of a package and cost.

2. Description of the Related Art

As to the semiconductor package technology for multi-chip stacks, it is an important issue to effectively resolve the profile of the package and the complexity of process steps. A large profile of a package is not suitable to portable consumer products, and products manufactured by a complex process will raise cost of manufacturing a lot.

FIG. 1 shows a cross-sectional view of a prior art semiconductor package for multi-chip stacks. A first chip 11 adheres with a second chip 12 and adheres on a first surface 13a of a substrate 13. In the wire bonding process, the I/O pads of the first chip 11 and second chip 12 are electrically connected to metal traces (not shown) of the first surface 13a of the substrate 13 by a plurality of bonding wires, as gold wires. The metal traces are further electrically connected to a plurality of solder balls 16 beneath a second surface 13b of the substrate 13 through conductive materials inside vias (not shown) of the substrate. The worst disadvantage in FIG. 1 is that a lot of bonding wires are used, thereby causing a thick profile.

FIG. 2 shows a cross-sectional view of a prior art semiconductor package for multi-chip stacks, which is disclosed in U.S. Pat. No. 5,608,262. The characteristic of the prior art semiconductor package is to electrically connect the first chip 11 to metal traces (not shown) of the first surface 13a of the substrate 13 through solder bumps 21. The substrate 13 has a hollow region, and the second chip 12 is placed in the hollow region of the substrate 13 and electrically connected to the first chip 11 through a plurality of solder bumps 21. The worst disadvantage is that the surface of the second chip 12 must grow a plurality of solder bumps first. After the first chip 11 and second chip 12 are adhered, an underfill process in the junction of the first chip 11 and second chip 12 and a curing process will need to follow up. The above process is too complicated and raises the cost of manufacturing. Besides, a redistribution layer (RDL) will need to be generated on the products and thereby raise the cost of manufacturing as well in a flip chip process.

FIG. 3 shows a cross-sectional view of a prior art semiconductor package for multi-chip stacks, which disclosed in R.O.C Pat. Publication No. 396571. The characteristic of the prior art semiconductor package is that the I/O pads of the first chip 11 are electrically connected to metal traces (not shown) of the first surface 13a of the substrate 13 by a plurality of bonding wires 17. The substrate 13 has a hollow region, and the second ship 12 is placed above the hollow region. The second chip 12 is adhered on a non-active surface of the first chip 11, and electrically connected to metal traces (not shown) of the second surface 13b of the substrate 13 by wire bonding process. Besides, the active surface of the first chip 11 is electrically connected to the first surface 13a of the substrate 13 by wire bonding process. The worst disadvantage of the semiconductor package in FIG. 3 is that the profile of the semiconductor package is too thick to fit the specification of consumer products.

### SUMMARY OF THE INVENTION

The first object of the present invention is to offer a semiconductor package having a thin profile.

The second object of the present invention is to offer a semiconductor package having a simple manufacturing process.

The third object of the present invention is to offer a semiconductor package having a smooth surface.

The fourth object of the present invention is to offer a semiconductor package which can be made by traditional process equipments.

For achieving the above purposes, the present invention discloses a semiconductor package which could be utilized in a BGA package or a flip chip package. The substrate of the semiconductor package has a hollow region, a first chip is placed above the hollow region of the substrate, and a second chip is adhered on the active surface of the first chip and placed in the hollow region of the substrate. The first chip is electrically connected to the substrate through a plurality of solder bumps, and the second chip is electrically connected to the substrate through a plurality of bonding wires.

Since the first chip of the semiconductor package according to the present invention is electrically connected to the substrate through a plurality of solder bumps, the total profile of the present invention after packaging is less than that of traditional packages structured by wire bonding in all connections. Furthermore, since the second chip is connected to the substrate by wire bonding process, a transfer mold could be used instead of dispensing process and thereby save much cost. Besides, since the first chip is adhered with second chip, the complex steps of the underfill and RDL process used in prior art will be omitted to save cost.

The semiconductor package for multi-chip stacks according to the present invention comprises a substrate, a first chip, a second chip, a plurality of solder balls, a first encapsulant body and a second encapsulant body. The substrate including a first surface and second surface has a hollow region and at least two layers of metal traces for transferring electrical signals. The first chip is placed above the hollow region of the first surface of the substrate, and is electrically connected to the metal traces of the substrate through a plurality of solder bumps. The second chip is adhered on an active surface of the first chip and placed in the hollow region of the substrate, and electrically connected to the metal traces of the substrate through a plurality of bonding wires. The plurality of solder balls are placed beneath the second surface of the substrate and electrically connected to the metal traces of the substrate. The first encapsulant body is used for encapsulating the first chip. The second encapsulant body is used for encapsulating the second chip and bonding wires.

The semiconductor package module for multi-chip stack comprises a substrate, a first chip assembly and a second chip assembly. The substrate includes a first surface and a second surface opposed to the first surface, and a hollow region on the substrate formed through the first and second surfaces. The first chip assembly is placed above the hollow region of the first surface of the substrate, and electrically connected to the metal traces of the substrate through a plurality of solder bumps. The second chip assembly is placed in the hollow region of the substrate and adhered on an active surface of the first chip, and electrically connected to the second surface of the substrate through a plurality of bonding wires.

### BRIEF DESCRIPTION OF THE DRAWINGS

The invention will be described according to the appended drawings in which:

FIG. 1 shows a cross-sectional view of a prior art semiconductor package for multi-chip stacks;

FIG. 2 shows a cross-sectional view of a prior art semiconductor package for multi-chip stacks;

FIG. 3 shows a cross-sectional view of a prior art semiconductor package for multi-chip stacks; and

FIG. 4 shows a cross-sectional view of an embodiment of a semiconductor package for multi-chip stacks according to the present invention.

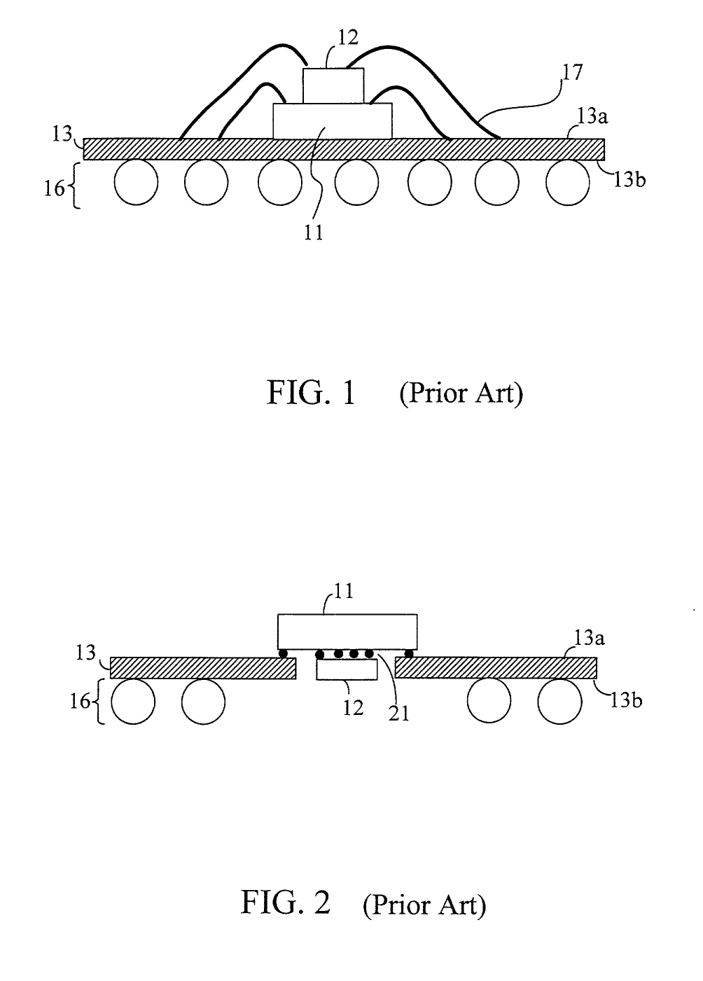

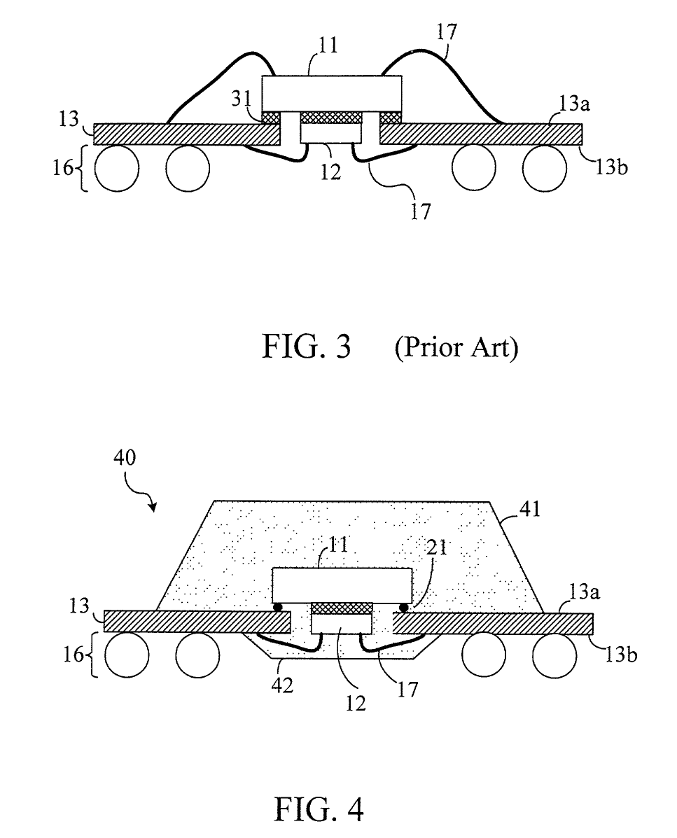

### PREFERRED EMBODIMENT OF THE PRESENT INVENTION

FIG. 4 shows a cross-sectional view of an embodiment of a semiconductor package for multi-chip stacks according to the present invention. The semiconductor package 40 comprises a substrate 13, a plurality of solder balls 16, a first chip 11, a second chip 12, a first encapsulant body 41 and a second encapsulant body 42. The substrate 13 has a hollow region made from polyimide, triazine, BT resin, phenolic resin, etc. Besides, the substrate 13 includes two conductive layers at least, and each conductive layer predefines metal traces to propagate electrical signals. The first chip 11 is placed above the hollow region of the first surface 13a of the substrate 13, and electrically connected to metal traces (not shown) of the substrate 13 through a plurality of solder bumps 21. Besides, a heat-dissipating device (not shown) could be optionally placed on the first chip 11 to enhance the efficiency of dissipation, or the heat-dissipating device could be placed on the first surface 13a of the substrate. The second chip 12 is placed in the hollow region of the substrate 13 and adhered to the active surface of the first chip 11 with an adhesive material, such as epoxy, B-stage epoxy or silica. The second chip 12 is electrically connected to the metal traces (not shown) through a plurality of bonding wires. The plurality of solder balls 16 are placed on the second surface 13b of the substrate 13, which could be electrically connected to the first chip 11 and second chip 12 through the metal traces of the substrate 13. The first encapsulant body 41 and second encapsulant body 42 can be formed by molding process for protecting the first chip 11 and second chip 12 from erosion by moisture and dust.

Based on the above technological characteristics, the present invention has the following advantages:

1. The profile of the present invention is thinner than that of the traditional package by wire bonding process.

2. Since the second chip 12 is connected by wire bonding, the process of a transfer mold can be utilized and omit dispensing process used in prior art.

3. A double side molding can be used in the present invention to keep smooth surfaces.

4. The process of underfill on bottom side would be omitted.

5. The process of RDL would be omitted to save cost.

Although the components of the above embodiments are represented as just first chip 11 and second chip 12, the present invention can still apply to semiconductor package of MCM titles including more than two chips. For example, on the non-active surface of the first chip 11, at least one chip could be further placed, which electrically connected to metal traces of the first surface 13a of the substrate by wire bonding, and the above procedure is called “first chip assembly”; or on the active surface of the second chip 12, at least one chip could be further placed, which is electrically connected to the second chip 12 or the second surface 13b of the substrate by solder bumps or bonding wires, and the above procedure is called “second chip assembly”.

The above-described embodiments of the present invention are intended to be illustrated only. Numerous alternative embodiments may be devised by persons skilled in the art without departing from the scope of the following claims.

What is claimed is:

1. A semiconductor package for multi-chip stacks, comprising:
a substrate having at least two layers of metal traces for transmitting electrical signals, the substrate including a first surface, second surface and a hollow region formed through the first and second surfaces;
a first chip having an active surface and a non-active surface, the first chip positioned above the hollow region of the first surface of the substrate and electrically connected to the metal traces of the substrate through a plurality of solder bumps;
a second chip positioned in the hollow region of the substrate and affixed to the active surface of the first chip by an adhesive, and the second chip being electrically connected to the metal traces of the substrate through a plurality of bonding wires;
a plurality of solder balls located on the second surface of the substrate to electrically connected to the metal traces of the substrate;
a first encapsulant body encapsulating the first chip; and a second encapsulant body encapsulating the second chip and bonding wires.

2. The semiconductor package of claim 1, further comprising a heat-dissipating device located on the non-active surface of the first chip.

3. The semiconductor package of claim 1, wherein the adhesive is selected from epoxy, B-stage epoxy or silica.

4. The semiconductor package of claim 1, further comprising a heat-dissipating device located on the first surface of the substrate.

5. The semiconductor package of claim 1, wherein the first and second encapsulant bodies are oppositely formed with the substrate by double side molding.

6. The semiconductor package of claim 1, which is processed by a transfer mold.

7. A modular structure for a semiconductor package for multi-chip stacks, comprising:
a substrate including a first surface, second surface and a hollow region formed through the first and second surface;
a first chip assembly having an active surface and a non-active surface, the first chip assembly positioned above the hollow region of the first surface of the substrate and electrically connected to the first surface of the substrate through a plurality of solder bumps; and
a second chip assembly positioned in the hollow region of the substrate and affixed to the active surface of the first chip by an adhesive, and the second chip assembly being electrically connected to the metal traces of the substrate through a plurality of bonding wires.

8. The modular structure of claim 7, wherein the substrate is provided with a plurality of layers of metal traces, thereby transmitting electrical signals between the first chip assembly and the second chip assembly through the plurality of solder bumps and bonding wires.

9. The modular structure of claim 8, further comprising a plurality of solder balls located on the second surface of the substrate for electrically connecting to the metal traces of the substrate.

10. The modular structure of claim 9, further comprising a first encapsulant body encapsulating the first chip assembly and solder bumps on the first surface of the substrate.

11. The modular structure of claim 7, wherein the adhesive is selected from epoxy, B-stage epoxy or silica.

12. The modular structure of claim 7, further comprising a heat-dissipating device located on the non-active surface of the first chip assembly.

13. The modular structure of claim 7, further comprising a heat-dissipating device located on the first surface of the substrate.

14. The modular structure of claim 10, wherein the first encapsulant body encapsulating on the first surface of the substrate and the second encapsulant body encapsulating on the second surface of the substrate is accomplished by double-side molding, thereby keeping smoothness.

15. The modular structure of claim 10, which is processed by a transfer mold.
